(19) United States
(12) Patent Application Publication
(10) Pub. No.: US 2025/0294669 A1
(43) Pub. Date: Sep. 18, 2025

(54) MOUNTING INTERFACE FOR HIGH SPEED ELECTRICAL CONNECTOR

(71) Applicant: Amphenol Corporation, Wallingford, CT (US)

(72) Inventors: Paul Galvin, Nashua, NH (US); David Levine, Amherst, NH (US); Marc B. Catier, JR., Durham, NH (US); Mark W. Gailus, Concord, MA (US); Vysakh Sivarajan, Nashua, NH (US)

(73) Assignee: Amphenol Corporation, Wallingford, CT (US)

(21) Appl. No.: 19/075,627

(22) Filed: Mar. 10, 2025

Related U.S. Application Data
(60) Provisional application No. 63/564,473, filed on Mar. 12, 2024.

(51) Int. Cl. H05K 1/02; H05K 1/11

(52) U.S. Cl. CPC H05K 1/0222; H05K 1/113; H05K 2201/09063; H05K 2201/09272; H05K 2201/093; H05K 2201/09618; H05K 2201/09636

(57) ABSTRACT

Described herein are mounting interfaces for electrical connectors capable of supporting high speed signals and having high density, including up to 70 GHz and higher. Some embodiments provide a connector footprint for a substrate having a pair of signal contact pads on a surface of the substrate and a pair of connecting traces that are interior to the substrate and electrically couple the signal contact pads to a first pair of signal vias (e.g., to a routing layer of the substrate). In some embodiments, a second pair of signal vias may electrically couple the signal contact pads to the connecting traces interior to the substrate. In some embodiments, a portion of a ground layer of the substrate may separate the signal contact pads in the pair. Mounting interfaces described herein enable operation at high frequencies without resonances or other degradation of signal integrity.

### CROSS-REFERENCE TO RELATED APPLICATIONS

This application claims priority to and the benefit of U.S. Provisional Patent Application No. 63/564,473, filed on Mar. 12, 2024, entitled “MOUNTING INTERFACE FOR HIGH SPEED ELECTRICAL CONNECTOR,” the contents of which are incorporated herein by reference in their entirety.

### FIELD

This patent application relates generally to interconnection systems, such as those including electrical connectors, used to interconnect electronic assemblies.

### BACKGROUND

This patent application relates generally to interconnection systems, such as those including electrical connectors, used to interconnect electronic assemblies.

Electrical connectors are used in many electronic systems. It is generally easier and more cost effective to manufacture a system as separate electronic assemblies, such as printed circuit boards (“PCBs”), which may be joined with electrical connectors. A known arrangement for joining several printed circuit boards is to have one printed circuit board serve as a backplane. Other printed circuit boards, called “daughterboards” or “daughtercards,” may be connected through the backplane.

A known backplane is a printed circuit board onto which many connectors may be mounted. Conducting traces in the backplane may be electrically connected to signal conductors in the connectors so that signals may be routed between the connectors. Daughtercards may also have connectors mounted thereon. The connectors mounted on a daughtercard may be plugged into the connectors mounted on the backplane. In this way, signals may be routed among the daughtercards through the backplane. The daughtercards may plug into the backplane at a right angle. The connectors used for these applications may therefore include a right angle bend and are often called “right angle connectors.”

Connectors may also be used in other configurations for interconnecting printed circuit boards. Some systems use a midplane configuration. Similar to a backplane, a midplane has connectors mounted on one surface that are interconnected by routing channels within the midplane. The midplane additionally has connectors mounted on a second side so that daughter cards are inserted into both sides of the midplane.

The daughter cards inserted from opposite sides of the midplane often have orthogonal orientations. This orientation positions one edge of each printed circuit board adjacent the edge of every board inserted into the opposite side of the midplane. The traces within the midplane connecting the boards on one side of the midplane to boards on the other side of the midplane can be short, leading to desirable signal integrity properties.

A variation on the midplane configuration is called “direct attach.” In this configuration, daughter cards are inserted from opposite sides of the system. These boards likewise are oriented orthogonally so that the edge of a board inserted from one side of the system is adjacent to the edges of the boards inserted from the opposite side of the system. These daughter cards also have connectors. However, rather than plug into connectors on a midplane, the connectors on each daughter card plug directly into connectors on printed circuit boards inserted from the opposite side of the system.

Regardless of the configuration of the connector, characteristics of the signal path through the connector can impact the speed of signals that can be passed through the connector with suitable signal integrity. Performance of any portion of the signal path could impact signal integrity. The characteristics of the mating interface of the connector, the mounting interface or intermediate portions between the mating and mounting interface, for example, might impact signal integrity by presenting a change of impedance along the signal path or introducing crosstalk.

### SUMMARY

Embodiments of the present disclosure provide a mounting interface for an electrical connector that exhibits low crosstalk and good impedance control at high frequencies (e.g., up to 70 GHz).

Some embodiments relate to a substrate. The substrate comprises an insulative body comprising a surface, a pair of signal vias, a pair of signal contact pads disposed on the surface, wherein contact pads of the pair are spaced from one another along a first line, and conductive traces interior to the substrate and electrically coupling respective signal contact pads of the pair of signal contact pads and signal vias of the pair of signal vias. Signal vias of the pair of signal vias are spaced from one another along a second line disposed at an angle with respect to the first line.

Some embodiments relate to a substrate. The substrate comprises a connector footprint. The connector footprint comprises a plurality of regions disposed in rows and columns. Each region comprises a pair of conductive pads on a surface of the substrate, a first pair of signal vias, wherein signal vias of the first pair are separated from one another along a first direction, and a second pair of signal vias, wherein signal vias of the second pair are separated from one another along a second direction that is orthogonal to the first direction, and wherein the first pair of signal vias interconnect respective ones of the pair of conductive pads and the second pair of signal vias. Each region further comprises conductive traces interconnecting respective ones of the second pair of signal vias and the first pair of signal vias.

Some embodiments relate to a substrate. The substrate comprises an insulative body comprising a surface, a pair of signal vias, a pair of signal contact pads disposed on the surface, conductive traces interior to the substrate and electrically coupling respective signal contact pads of the pair of signal contact pads and signal vias of the pair of signal vias, and a ground layer above the conductive traces interior to the substrate, the ground layer comprising a pair of antipads, each antipad of the pair aligned with a signal contact pad of the pair of signal contact pads.

Some embodiments relate to a substrate. The substrate comprises insulative material comprising a surface, a pair of signal vias, a pair of signal contact pads disposed on the surface, wherein contact pads of the pair are spaced from one another along a first line, and conductive traces electrically coupling respective signal contact pads of the pair of signal contact pads and signal vias of the pair of signal vias. At least some of the insulative material is disposed between the pair of signal contact pads and the conductive traces, and signal vias of the pair of signal vias are spaced from one another along a second line disposed at an angle with respect to the first line.

Some embodiments relate to a substrate comprising a connector footprint. The connector footprint comprises a plurality of regions disposed in rows and columns. Each region comprises a pair of signal contact pads separated from one another along a first direction, and conductive material configured as a ground plane. The conductive material comprises a first portion on a first side of the pair of signal contact pads, a second portion on a second side of the pair of signal contact pads that is opposite the first side along a second direction transverse to the first direction, and a third portion disposed between the pair of signal contact pads that connects the first portion to the second portion.

These techniques may be used alone or in any suitable combination. The foregoing summary is provided by way of illustration and is not intended to be limiting.

### BRIEF DESCRIPTION OF THE DRAWINGS

The accompanying drawings may not be drawn to scale. In the drawings, each identical or nearly identical component that is illustrated in various figures may be represented by a like numeral. For purposes of clarity, not every component may be labeled in every drawing.

FIG. 1A is a sketch of a portion of a baseline footprint for mounting a pair of signal conductors of a connector to a substrate, such as a printed circuit board, with the insulative portions of the PCB shown transparent.

FIG. 1B is a side view of the baseline footprint of FIG. 1A taken at a cross-section along A.

FIG. 1C is a side view of the baseline footprint of FIG. 1A taken at a cross-section along line B.

FIG. 2 is a plan view of a routing layer within the portion of the baseline footprint of FIG. 1A.

FIG. 3A is a sketch of a portion of a footprint for mounting a pair of signal conductors of a connector to a substrate, such as a printed circuit board, with the insulative portions of the PCB shown transparent.

FIG. 3B is a sketch of the portion of the footprint of FIG. 3A, with the ground plane above the connecting trace additionally shown transparent.

FIG. 3C is a side view of the footprint of FIGS. 3A-3B taken at a cross-section along line A′.

FIG. 3D is a side view of the footprint of FIGS. 3A-3B taken at a cross-section along line B′.

FIG. 4A is a sketch of the portion of the footprint of FIG. 3A, with the insulative material of the PCB and the ground layers shown transparent, without removal of portions of the second signal vias extending above the connecting traces removed.

FIG. 4B is a side view of the footprint of FIG. 4A taken at a cross-section along a line that corresponds to line B′ in FIG. 3B.

FIG. 5A is a sketch of the portion of the footprint of FIG. 3A, with wider connecting traces.

FIG. 5B is a sketch of the portion of the footprint of FIG. 5A, with the ground plane above the connecting trace additionally shown transparent.

FIG. 6 is a plot of insertion loss as a function of frequency for the baseline design of FIGS. 1A-1C and three example footprints of improved design, as shown in FIGS. 3A-3D, 4A-4B and 5A-5B.

### DETAILED DESCRIPTION

The inventors have developed techniques for making electronic assemblies capable of supporting high speed signals and having high density, including at 70 GHz and higher. These techniques include designs for a mounting interface of the connector that enable operation at high frequencies without resonances or other degradation of signal integrity. The mounting interface may be used with a connector having individually shielded modules each with a pair of signal conductors, providing low crosstalk and good impedance control.

Signal conductors of the connector may be connected at their distal edges to pads on a surface of a substrate, an example of which is a printed circuit board (PCB). The signal conductors, for example, may be pressure mounted to a PCB. The signal conductors may have compliant portions extending perpendicular to the surface of the printed circuit board such that, upon pressing the connector against the PCB, the signal conductors compress, with the compliant portions generating a spring force that presses the edges of the signal conductors against the pads.

The signal conductors may be shaped to reliably form an edge-to-pad pressure mount connection. In some examples, the distal ends of the signal conductors may form a tip that can break through an oxide layer or other contaminants on the pad. Alternatively or additionally, the signal conductors may be configured to twist as they are compressed. Twisting may further aid in breaking through oxide or other contaminants on the pad.

In other examples, an edge-to-pad connection may be made using surface mount soldering techniques.

In some examples, signal conductors of the connector may be configured to carry differential signals. Pairs of signal conductors may pass through the connector with the intermediate portions of the signal conductors arranged for broadside coupling. Broadside coupling in a right angle connector may provide for low skew interconnects when the signal conductors of a pair are aligned in a row direction parallel to an edge of a PCB at which the connector is mounted.

As changes in geometry along a signal path may contribute to changes in impedance, mode conversion, or other artifacts that degrade signal integrity, high signal integrity may be achieved with mounting ends of the signal conductors aligned with intermediate portions of the signal conductors adjacent the mounting interface. Edge-to-pad mounting onto pads of a PCB that are similarly aligned with those intermediate portions of the signal conductors avoids changes in geometry along the signal path and similarly promotes signal integrity.

Despite positioning of the pads on the PCB for a connector footprint to align with signal conductors within a connector, signal vias connecting those pads to traces within the PCB may be positioned to enable efficient routing of those traces out of the connector footprint. The inventors have recognized and appreciated techniques to provide good signal integrity, even at high frequencies, and efficient routing, which contributes to cost-effective design of an electronic system using the connector. An appropriate transition region within the PCB may enable the pads, positioned to align with signal conductors of the connector, to connect with vias positioned for efficient routing of signal traces in the PCB, while providing good signal integrity.

The transition region may include pairs of pads aligned in a first line and pairs of vias aligned in a second line. The first line may be transverse to the second line. In some embodiments, the first line and the second line may be orthogonal, supporting broadside coupling within the connector and vertical routing channels within the PCB. The pads and vias may be connected with surface traces.

As a result, the pairs of signal vias may be aligned in a column direction, supporting vertical routing of signal traces out of the connector footprint, even if the signal conductors of the corresponding pairs within the connector are aligned in a row direction. Moreover, as the signal vias do not receive press-fits, they can be small, such as less than 12 mils in diameter, for example. Small diameter vias enable wide routing channels, which enable more traces per layer to be routed out of the connector footprint and reduce the number of layers required to route all signals out of the connector footprint. Such a design provides both efficient routing of traces and high signal integrity.

That transition region may include first vias connected to the surface pads to which signal conductors of a connector are connected. Those first vias may route signals to a first interior layer of the PCB where first traces may connect the first vias to second vias. The second vias may make connections to second traces on a second interior layer acting as a routing layer. Traces on the routing layer may route signals out of the connector footprint. At least one ground plane may be disposed above the first interior layer. Openings in that ground plane may be shaped to provide very high frequency operation without degradation of signal integrity. In some examples, the surface pads may be co-planar with a ground plane. Alternatively or additionally, the first interior layer may be separated from the surface pads by a ground plane. The openings may form antipads in the vicinity of the surface pads. A ground plane optionally may include openings through which to drill away stubs from vias of the transition region.

These techniques may be used separately or together, in any suitable combination. As a result of improved electrical properties achieved by these techniques, electrical connectors and electronic assemblies described herein may be configured to operate with high bandwidth for a high data transmission rate. For example, electrical connectors and electronic assemblies described herein may operate at 60 GHz, 65 GHZ, 70 GHz, and/or above and may have a bandwidth of at least 70 GHz, such as a frequency up to and including 70 GHz and/or bandwidth in the range of 60-80 GHz, such as 60-70 GHz. Such electrical connectors and electronic assemblies may pass data at rates up to 224 Gb/s, for example.

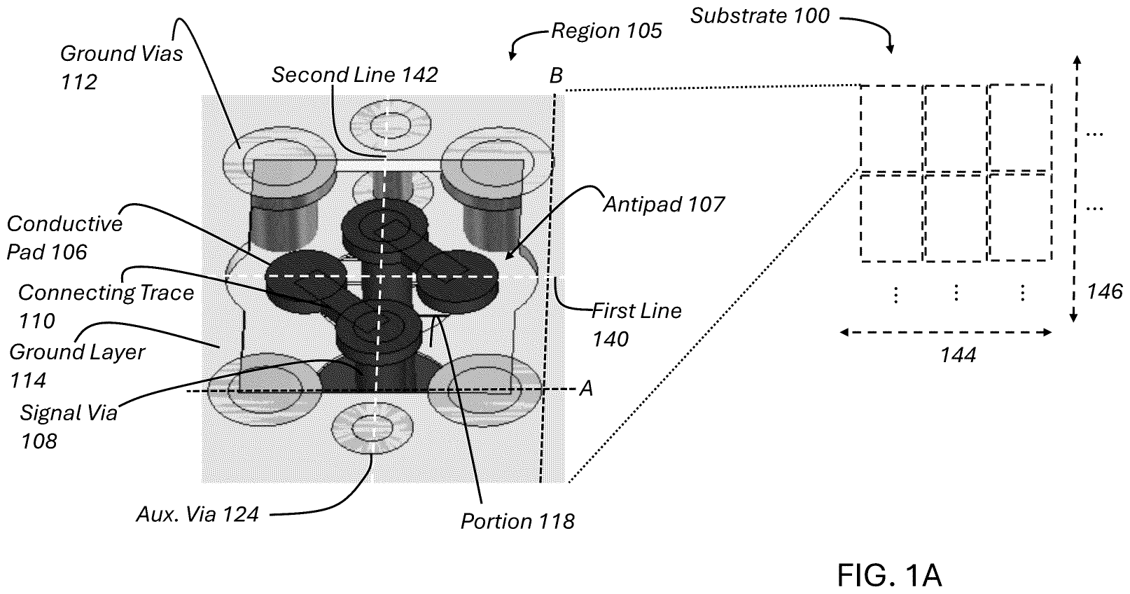

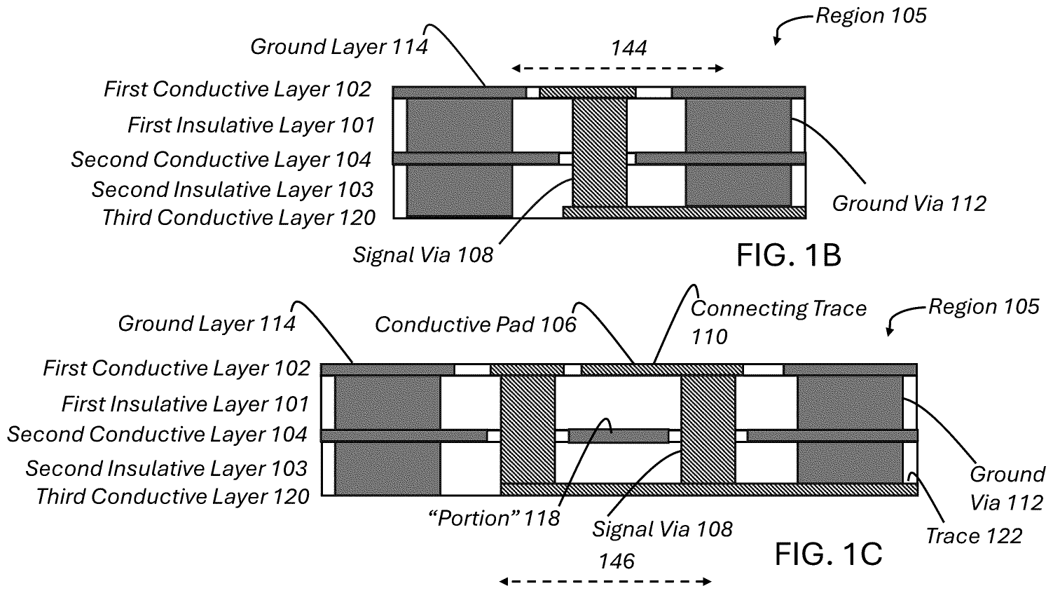

FIG. 1A is a perspective view of a region 105 of a substrate 100 having a Baseline Footprint for mounting a connector, which may be as described in U.S. Pat. No. 11,637,403. FIG. 1B is a view taken from a cross-section of the region 105 of the substrate 100 along line A in FIG. 1A. FIG. 1C is a view taken from a cross-section of the region 105 of the substrate 100 taken along line B in FIG. 1A. In these cross-sectioned views, metal structures are depicted as if the insulative matrix of the substrate were transparent.

In some embodiments, a connector footprint may include a plurality of regions each configured as shown for region 105. Each region may have a pair of signal contact pads 106 configured for making contact with a pair of contact tails of a connector and ground vias 112 around the signal contact pads 106. Larger ground vias 112 may be configured for receiving shield tails of the connector that extend from shielding around the pair of contact tails. Smaller ground vias (e.g., auxiliary vias 124) may be configured to provide additional shielding in the substrate 100 between signals propagating in adjacent regions.

In some embodiments, the region 105 illustrated in FIGS. 1A, 1B and 1C may correspond to the structures in the substrate 100 that connect with the tails of signal conductors and shields of a connector module. Accordingly, the illustrated portion may correspond to the footprint for one module, and may be replicated for each like module of a connector that is mounted to the substrate 100.

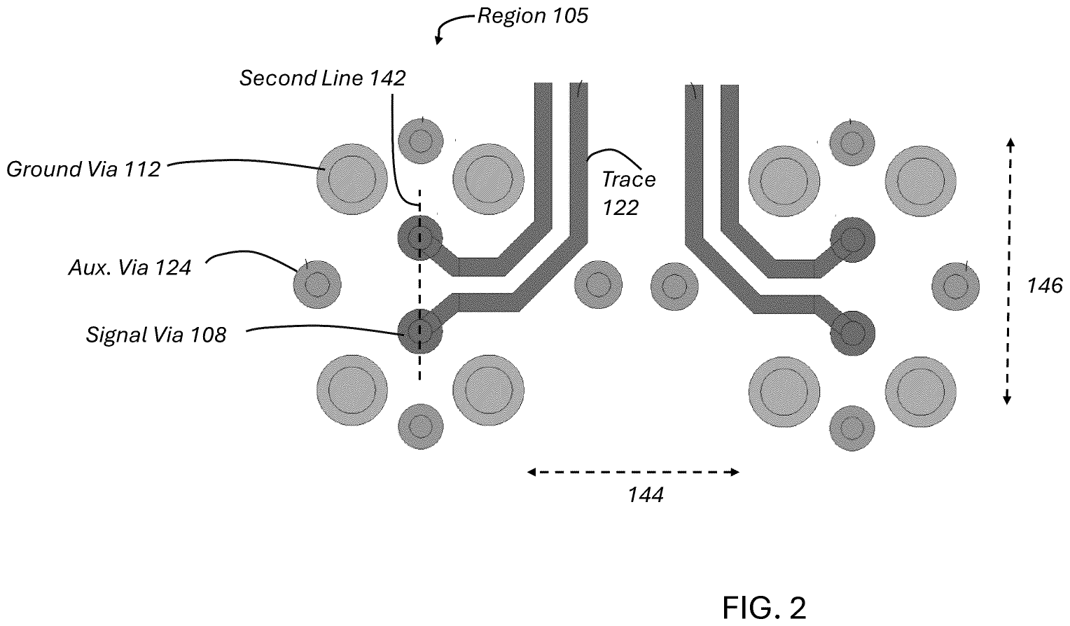

In some embodiments, substrate 100 may be a printed circuit board. FIG. 1A illustrates a first conductive layer 102 of a printed circuit board where a transition region is implemented. As shown in FIG. 1B, the printed circuit board further has second conductive layer 104 and third conductive layer 120. Third conductive layer 120 (FIG. 2) is configured to route signal traces and second conductive layer 104 is configured as a ground layer that separates first conductive layer 102 from third conductive layer 120. A first insulative layer 101 separates first conductive layer 102 from second conductive layer 104 and a second insulative layer 103 separates second conductive layer 104 from third conductive layer 120. Alternative or additional layers may be included depending on the embodiment.

In some embodiments, first and second conductive layers 102 and 104 may be disposed on opposing surfaces of insulative layer 101. For example, insulative material of insulative layer 101 may include fiberglass (e.g., FR-4) having copper plated on surfaces thereof using printed circuit board fabrication processes. Substrate 100 may also include one or more vias, such as vias 108 and 112, which may be drilled through the insulative material of insulative layer(s) 101, 103. Substrate 100 may include an array of the regions 105 illustrated in FIGS. 1A-IC.

Conductive layers of substrate 100 may be configured for coupling to an electrical connector. For instance, first conductive layer 102, which may be a top-most layer of substrate 100, includes contact pads 106 that may be configured for attaching and/or electrically connecting to contact tails of an electrical connector. As shown in FIGS. 1A-1C, contact pads 106 may be configured to receive pairs of contact tails carrying components of a differential signal and to provide the differential signal components to signal vias 108. In this example, the contact pads 106 may be positioned to align with a distal edges of the contact tails of a pair of signal conductors configured for broadside coupling in the connector. Contact pads 106 may be exposed to facilitate physical contact between contact pads 106 and the contact tails of the connector when mounted. The contact pads 106 may be plated with gold or other noble metal, or other plating that resists oxidation for a reliable pressure mount connection.

In one example, contact tails of a connector may be pressure-mounted to contact pads 106. In another example, contact tails of a connector may be soldered to contact pads 106 using butt joints. In some embodiments, contact pads 106 may have a diameter between 10 and 14 mils or between 11 and 13 mils.

Portions of first conductive layer 102 may be configured for contacting a ground structure of a connector mounted to substrate 100. For instance, some locations of ground plane portion 114 may be configured to receive electromagnetic shielding tails of the electrical connector. Such portions may be exposed to facilitate physical contact between the exposed portions and the shielding tails when the connector is mounted. In the illustrated embodiment, connection is made with press-fit contact tails extending from the shields of each module. The shielding contact tails may be inserted into vias 112.

Ground plane portion 114 may be electrically connected to vias 112, such that vias 112 are ground vias. Signal vias 108 may be electrically isolated from ground portion 114. As shown, vias 108 are within an antipad 107 of ground plane portion 114. Other antipads in other ground plane layers within the printed circuit board may be provided concentric with signal vias 108 that may separate vias 108 from the ground structures of substrate 100. In contrast, ground vias 112 may be electrically coupled to second conductive layer 104, which may also be grounded. In some embodiments, ground vias 112 may have a drilled diameter of less than 16 mils, but greater than 10 mils, to accommodate a press-fit.

Signal vias 108 may be electrically coupled to third conductive layer 120 and/or additional conductive layers of substrate 100, which may serve as signal routing layers. Third conductive layer 120 may have signal traces coupled to vias 108 (FIG. 2) may be positioned adjacent second conductive layer 104, with second insulative layer 103 positioned between second conductive layer 104 and third conductive layer 120, such as shown in FIGS. 1B-1C, or additional insulative layers may be positioned between the second conductive layer 104 and the third conductive layer 120.

In some embodiments, vias 108 may have a drilled diameter of less than 10 mils. In some embodiments, vias 108 may have a drilled diameter between 7 and 9 mils. As shown in FIG. 1A, contact pads 106 are spaced from one another along first line 140, and vias 108 are spaced from one another along second line 142. In some embodiments, first line 140 and second line 142 may be disposed at an angle of at least 45 degrees with respect to one another. For example, in FIG. 1A, first line 140 and second line 142 are perpendicular to one another. Line 140, for example, may be parallel to an edge (not shown) of the PCB adjacent the illustrated footprint. Line 142 may be perpendicular to the edge.

Conductive traces 110 connect contact pads 106 to vias 108. In the illustrated embodiment, conductive traces 110 are elongated at an angle of about 45 degrees with respect to second line 142. The conductive traces 110 may serve to gradually transition the relative positioning of contact pads 106 to the relative positioning of vias 108. Portions 118 of second conductive layer 104 may be positioned adjacent conductive traces 110, with insulative layer 101 separating portions 118 from conductive traces 110.

In some embodiments, second conductive layer 104 may be spaced within a few millimeters of first conductive layer 102 so as to provide a ground reference for the conductive traces 110. Portions 118 may accommodate the transition from the relative positioning of contact pads 106 to the relative positioning of vias 108. A ground reference, coupled to both the shields within the connector that serve as reference for the signal conductors in the connector and the ground planes that serve as a ground reference for traces within the substrate, enables continuity of ground current referenced to the path carrying the differential signal throughout the transition. Such a ground reference further promotes transition of the signal paths without mode conversion or other undesired signal integrity characteristics. Avoiding mode conversion for a connector module with shields per pair may avoid exciting resonances within the shields of the module and provide improved signal integrity. Moreover, the straight-through configuration of the mounting ends of the signal conductors enables the largest dimension of the shield to be smaller than if a transition or other geometry change were included in the module. Such a configuration may provide for a high frequency of the lowest resonant mode supported by the shields, which further contributes to high frequency operation of the connector.

For example, signal conductors of a mounted connector may be broadside coupled to one another adjacent substrate 100, with the signal conductors spaced from one another along first line 140. Rather than transitioning the broadside coupled signal conductors to edge coupled contact tails for mounting to substrate 100, the connector may have broadside coupled contact tails, and the transition may be achieved using traces 110, such that the signals are edge coupled at vias 108. In some embodiments, an electrical connector mounted to substrate 100 may transmit differential signals with less than −40 dB of suck out loss over the frequency range of 25 GHz to 56 GHz. However, as described further herein including in connection with FIG. 6, the baseline footprint shown in FIGS. 1A-1C may exhibit greater suck out loss above 60 GHz, such as between 60 GHz and 70 GHZ.

FIG. 1A further illustrates portions of an exemplary substrate 100 including an array of the region 105 of substrate 100 illustrated in FIGS. 1A-1C. As shown in FIG. 1A, the regions 105 are disposed in a rectangular array having rows along a row direction 144 and columns along column direction 146. In the illustrated example, the first line 140 runs parallel to the row direction 144 and the second line 142 runs parallel to the column direction 146. Each region 105 of the connector footprint may be configured as shown for the illustrated region 105. For instance, each region 105 may have a like pair of signal vias (e.g. 108) and a like pair of conductive contact pads (e.g., 106), and like traces (e.g., 110) interconnecting ones of the pairs of signal vias with ones of the pairs of contact pads. Also, where second lines separating signal vias of each pair run parallel to column direction 146 such as in FIG. 1A, signal vias of each pair may be thus separated from one another along column direction 146. Similarly, where first lines separating contact pads of each pair run parallel to row direction 144, contact pads of each pair may be thus separated from one another along row direction 144.

In some embodiments, the ground layer 114 may extend throughout the connector footprint. For example, the ground layer 114 may be configured as a ground plane for the connector footprint, and/or may provide shielding between regions of the connector footprint.

Spacing between vias 108 and/or ground vias 112 on substrate 100 may be adapted to match the spacing of pairs of contact tails and/or electromagnetic shielding tails of a mounting electrical connector, for example. Accordingly, closer spacing between signal conductors and/or smaller spacing between signal conductors and ground conductors will yield a more compact footprint. Alternatively or additionally, more space will be available for routing channels. Further, closer spacing may enable the largest dimension of the shielding enclosure for a module to be mounted to the footprint to be reduced, thereby increasing the operating frequency range of the connector.

In some embodiments, contact tails of an electrical connector may be implemented with superelastic conductive materials, which may enable smaller vias and closer spacing between adjacent pairs than for conventional contact tails.

Such close spacing may be achieved, by thin contact tails, such as may be implemented with superelastic wires of a diameter less than 10 mils, for example. In some embodiments, contact tails of connectors described herein may be configured to be inserted into plated holes formed with an unplated diameter of less than or equal to 20 mils. In some embodiments, the contact tails may be configured to be inserted into vias drilled with an unplated diameter of less than or equal to 10 mils. In some embodiments, the contact tails may each have a width between 6 and 20 mils. In some embodiments, the contact tails may each have a width between 6 and 10 mils, or between 8 and 10 mils in other embodiments. In some embodiments, each region 105 of the connector footprint may have an area of less than 2.5 mm². For instance, columns of the connector footprints may be separated center-to-center by less than 2.5 mm in column direction 146, and rows of the connector footprint may be separated center-to-center by less than 2.5 mm in row direction 144.

As further shown in FIG. 1A, first conductive layer 102 includes auxiliary vias 124 positioned on opposite sides of signal vias 108. In some embodiments, auxiliary vias 124 may be configured to provide additional electromagnetic shielding between adjacent pairs of signal vias 108. For example, auxiliary vias 124 may extend from first conductive layer 102 to second conductive layer 104 and/or third conductive layer 120. In some embodiments, auxiliary vias 124 may have a smaller diameter than ground vias 112, which may allow for positioning of auxiliary vias 124 in places too small to accommodate a ground via 112. For example, in some embodiments, ground vias 112 may have a drilled diameter of less than 16 mils and greater than 10 mils, and auxiliary vias 124 may have a drilled diameter of less than 10 mils, such as less than 8 mils and greater than 5 mils.

As shown in FIGS. 1C, signal vias 108 may connect to third conductive layer 120, and traces 122 may route signals from vias 108 to other portions of substrate 100. For example, third conductive layer may support connections to one or more electronic devices, such as microprocessors and/or memory devices, and/or other electrical connectors, mounted in the central portion of the PCB and to which traces 122 may connect. The signal vias 108 may terminate at the routing layer at which they connect. Such a configuration may be achieved by back-drilling the portions of the signal vias that extend beyond the routing layer. Ground vias 112 may also extend partially into the PCB, for example extending only so far as is necessary to receive a press-fit. However, in other embodiments, the signal and or ground vias may extend further into the PCB than illustrated in FIG. 1C.

FIG. 2 is a schematic view of third conductive layer 120 of substrate 100 within region 105 and another region that is adjacent region 105 along row direction 144. The third conductive layer 120 is shown in FIG. 2 configured as a routing layer. Conductive traces 122 on the third conductive layer 120 route signals received via the signal contact pads 106 to other locations on the substrate 100. The conductive traces 110 that interconnect the signal contact pads 106 and signal vias 108 may facilitate efficiently routing the conductive traces 122 on the third conductive layer 120. For instance, the conductive traces 122 on the third conductive layer 120 may be elongated in a first direction (e.g., the column direction 146) while having the signal contact pads 106 separated in a second direction (e.g., the row direction 144). Such a configuration may facilitate mounting a connector with broadside-coupled contact tails to a substrate where signals are to be routed in a direction orthogonal to the direction of the broadside-coupling for space-efficient routing.

As shown in FIG. 2, traces 122 may extend in column direction 146 (e.g., between pairs of vias in adjacent ones of the columns), such as perpendicular to an edge of the substrate 100 to which the region 105 is adjacent. In some embodiments, the conductive layer 120 may support a routing channel wide enough for two pairs of traces 122 to be routed through that channel. For instance, in FIG. 2, two pairs of traces 122 are routed between vias 108 of region 105 and the region adjacent region 105 along row direction 144. In some embodiments, a connector footprint may have one routing layer for every two rows that must be routed out of the footprint. As adding routing layers in a printed circuit board may increase cost, efficient routing of two rows per layer may lead to lower cost PCBs.

In some embodiments, auxiliary vias 124 may be disposed on at least three sides of signal vias 108. For example, as shown in FIG. 2, traces 122 are routed between two ground vias 112 and then between a ground via 112 and a further auxiliary via 124. In some embodiments, the configuration shown in FIG. 2 may provide increased shielding for traces 122.

According to some embodiments of the present disclosure, an improved connector footprint implemented on a substrate may have a pair of signal contact pads on a surface of the substrate and conductive traces interior to the substrate electrically coupling the signal contact pads to a pair of signal vias. For example, at least some of the insulative material of the substrate may be disposed between the signal contact pads and conductive traces. Such a configuration frees space on the surface of the substrate for portions of the ground layer to run between the signal contact pads and/or proximate the conductive traces, which improves performance of the footprint at higher frequencies as described further below.

In some embodiments, the signal contact pads may be spaced from one another along a first line and the signal vias may be spaced from one another along a second line disposed at an angle with respect to the first line. For example, the conductive traces may provide an angular transition from the spacing between the signal contact pads to the spacing between the signal vias that is interior to the substrate. Accordingly, traces on a routing layer of the substrate may extend at an angle with respect to spacing between the signal contact pads on the surface, and thus the direction in which signals are routed within the substrate and the orientation of the contact tails of the connector mounted to the substrate need not depend on one another in some embodiments.

In some embodiments, a ground layer above the conductive traces may have a pair of antipads, each antipad aligned with a signal contact pad of the signal contact pads. Portions of the ground layer between the signal contact pads (e.g., between the antipads) may push resonant modes in the ground layer above the operating frequency band of signals propagating in the footprint. Portions of the ground layer that lie proximate to the conductive traces (e.g., adjacent the antipads) may provide shielding and/or impedance control for the conductive traces.

According to some embodiments of the present disclosure, an improved connector footprint implemented on a substrate may have conductive pads on a surface of the substrate, a first pair of signal vias, a second pair of signal vias that are interconnected to respective conductive pads by the first pair of signal vias. The first signal vias may be separated from one another along a first direction and the second signal vias may be separated from one another along a second direction that is orthogonal to the first direction, with conductive traces interconnecting respective ones of the second vias and the first vias. Such a configuration allows the first signal vias at the surface to have different dimensions (e.g., diameter, inter-pair spacing) than the second signal vias, for which some dimensions may be limited by other layers the second signal vias pass through.

According to some embodiments, an improved connector footprint implemented on a substrate may have a pair of signal contact pads and conductive material configured as a ground plane having first and second portions disposed on opposite sides of the signal contact pads and a third portion between the signal contact pads that connects the first portion to the second portion. For example, the first and second portions may form at least a partially closed cavity around the signal contact pads, and the third portion may pass through the partially closed cavity. The third portion may be configured to push resonant modes in the cavity above the operating frequency band of signals propagating in the footprint.

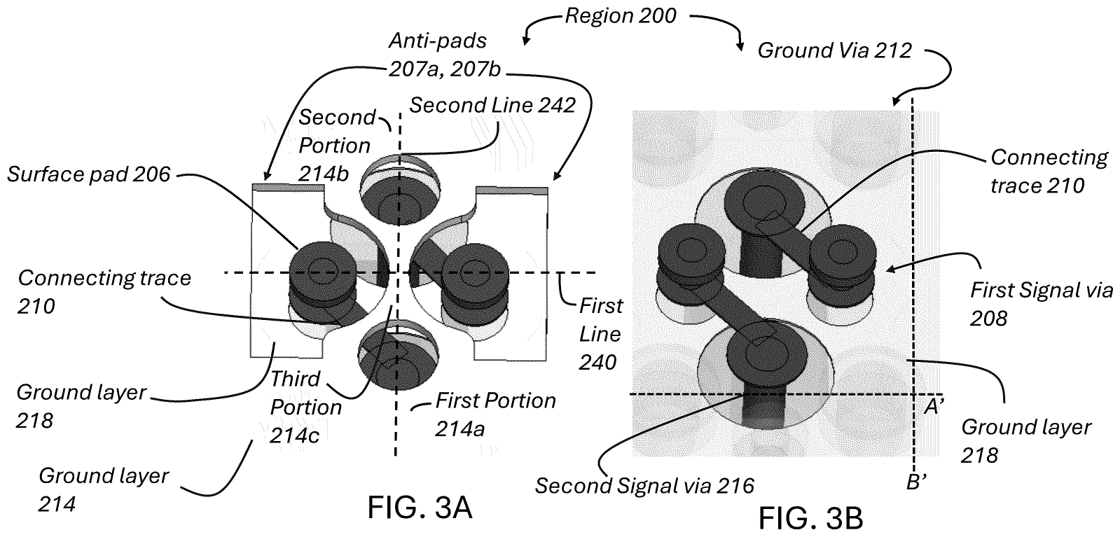

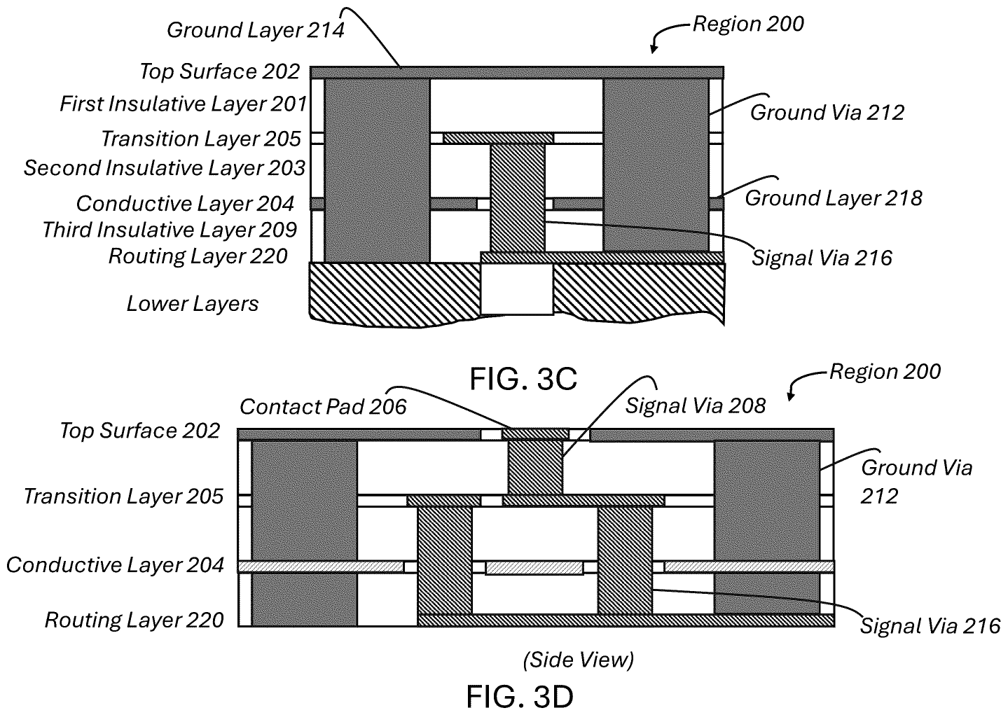

FIGS. 3A-3D illustrate an improved design of the portion of a connector footprint illustrated in FIGS. 1A-1C to support operation at higher frequencies with low suck out loss. FIG. 3A shows a region 200 of a substrate (e.g., 100); FIG. 3B shows the region 200 with ground layer 214 hidden from view. FIGS. 3C-3D show side views of the region 200 taken at cross-sections along lines A′ and B′, respectively, in FIG. 3B.

In some embodiments, region 200 may be configured in some respects as described herein for region 105. For example, in FIGS. 3A-3B, the region 200 includes a pair of signal contact pads 206 on a top surface 202 (FIG. 3C) of the substrate, which are separated along a first line 240. The region 200 further includes a pair of signal vias 216 to a routing layer 220 (FIG. 3C), which are separated along a second line 242. Such a configuration allows a connector having contact tails separated along first line 240 to be mounted to the substrate while routing signals in traces within the substrate (e.g., 122 in FIG. 2) extending parallel to the second line 242.

In some embodiments, the second line 242 may be disposed at an angle with respect to the first line 240. For example, the angle may be greater than 0 degrees and less than 180 degrees. In some embodiments, the angle between first line 240 and second line 242 may depend on the configuration of the connector that the footprint is configured to receive and/or the direction in which routing traces within the substrate extend. For instance, the first line 240 may depend on the direction in which contact tails of a pair are separated in the connector and the second line 242 may depend on the direction in which routing traces within the substrate extend.

In some embodiments, the angle between first line 240 and second line 242 may be between 45 degrees and 135 degrees. For example, an angle of 45 degrees or 135 degrees may be useful for mounting a connector in which pairs of contact tails are disposed in an array with inter-pair separation in a row or column direction of the array and intra-pair spacing that is at an angle (e.g., between 30 and 60 degrees, such as 45 degrees) with respect to the row or column direction. In some embodiments, the first line 240 may be orthogonal to the second line 242, such as described above in connection with FIGS. 1A-1C.

In contrast to FIGS. 1A-1C, connecting traces 210 of region 200 that interconnect the signal contact pads 206 and signal vias 216 may be interior to the substrate. For example, at least some insulative material of the substrate (e.g., first insulative layer 201 in FIG. 3C) may be disposed between the signal contact pads 206 and the connecting traces 210. For instance, the connecting traces 210 may be in an interior layer of the substrate. In the example of FIG. 3C, the illustrated conductive traces 210 are on a transition layer 205, which is disposed between a top surface 202, having the signal contact pads 206, and a conductive layer 204 having a ground layer 218. In some embodiments, having the signal contact pads 206 and the connecting traces 210 on different layers of the substrate allows ground layers 214 and 218 to be above and below the layer with the connecting trace 210, respectively. Such a structure may provide a transition from signal conductors within the connector to signal conductors within the PCB that provides improved signal integrity at high frequencies.

As further shown in FIGS. 3C-3D, the substrate includes a first insulative layer 201 between the top surface 202 and the transition layer 205, a second insulative layer 203 between the transition layer 205 and the conductive layer 204, and a third insulative layer 209 between the conductive layer 204 and the routing layer 220. It should be appreciated that additional or alternative layers may be present, for example additional routing layers and/or conductive layers having ground portions. In some embodiments, the substrate may be configured as a multi-layer PCB in which some or all insulative layers include a laminate material such as fiberglass and some or all conductive layers include conductive material patterned onto the laminate material. Vias may be formed by drilling holes into the laminate material and plating the holes with conductive material.

In some embodiments, ground vias 212 in the substrate may extend from surface 202 to conductive layer 204. While not shown in FIGS. 3C-3D, ground vias 212 may extend beyond conductive layer 204 to routing layer 220 such as shown in FIG. 2. Further, in some embodiments, ground vias 212 may extend beyond routing layer 220, such as to a further conductive layer after routing layer 220.

In further contrast to FIGS. 1A-IC, a pair of signal vias 208 may electrically couple the signal contact pads 206 to the connecting traces 210. For example, as shown in FIG. 3A, the pair of signal vias 208 are separated along first line 240. In the illustrated embodiment, the pair of signal vias 208 are aligned with signal contact pads 206, though in other embodiments the pair of signal contact pads 206 may be connected to the pair of signal vias 208 by connecting traces.

In some embodiments, the conductive material of the ground layer 214 may have first and second portions on opposite sides of the signal contact pads 206 and a third portion disposed between the signal contact pads 206 connecting the first and second portions. For example, in FIG. 3A, the ground layer 214 has a first portion 214a on a first side of signal contact pads 206, a second portion 214b on a second side of signal contact pads 206 that is opposite the first side, and a third portion 214c disposed between signal contact pads 206 that connects the first portion 214a to the second portion 214b. In the illustrated embodiment, the first portion 214a and the second portion 214b are opposite one another along second line 242, which is transverse to first line 240 that separates the signal contact pads 206. As shown in FIG. 3A, the second line 242 may bisect the third portion 214c

In some embodiments, the ground layer 214 may have a pair of antipads 207a, 207b, each antipad of the pair aligned with a signal contact pad of the pair of signal contact pads 206. For example, as shown in FIG. 3A, each signal contact pad 206 is disposed within one of the antipads 207a, 207b. In the illustrated example, portion 214c of the ground layer 214 is between the antipads 207a, 207b and between the signal contact pads 206.

In some embodiments, the ground layer 214 may have a first ground portion at least partially surrounding the signal contact pads 206 and a second ground portion between the signal contact pads 206. For example, as shown in FIG. 3A, the first portion 214a is on a first side of the signal contact pads 206 (e.g., along second line 242), the second portion 214b is on a second side of the signal contact pads 206 (e.g., along second line 242), and the third portion 214c is between the signal contact pads 206. In some embodiments, the first ground portion may form an aperture around the signal contact pads 206 and the second ground portion may interconnect the ground layer 214 across the aperture from a first side of the aperture to a second side of the aperture. For example, third portion 214c may connect first portion 214a to second portion 214b, thereby splitting the aperture formed by ground layer 214 around signal contact pads 206 into a pair of smaller apertures formed by the pair of antipads 207a, 207. For instance, the aperture formed by each antipad 207a, 207b may have a diameter around a respective signal contact pad 206 that is at least 50% shorter than a diameter of the aperture formed by the ground layer 214 around both signal contact pads 206. Because each of the antipads 207a, 207b provides a smaller diameter than the aperture without third portion 214c, the lowest frequency cavity resonance in each antipad 207a, 207b is higher than the lowest frequency cavity resonance in the aperture.

In some embodiments, conductive material of the ground layer 214 may surround the signal contact pads 206 on at least three sides. For example, signal contact pads 206 may be surrounded on the first side by the first portion 214a, on the second side by the second portion 214b, and on a third side by third portion 214c that connects the first portion 214a to the second portion 214b. In some embodiments, the ground layer 214 may further surround the signal contact pads 206 on a fourth side opposite the third portion 214c along the first line 240. For example, as shown in FIG. 3A, each antipad 207a, 207b is fully surrounded by the ground layer 214 and thus the ground layer 214 has fourth portions connecting the first portion 214a to the second portion 214b on opposite sides, respectively, of the signal contact pads 206 along the first line 240. In some embodiments, the ground layer 214 may be offset from connecting traces 210 in a direction towards surface 202 of the substrate. In the example illustrated in FIGS. 3A-3D, the ground layer 214 above is the uppermost ground layer the PCB. Compared to the example of FIGS. 1A-1C and 2, the example of FIG. 3A shows the uppermost ground layer 214 of the PCB to have multiple smaller antipads 207a and 207b rather than one larger antipad encircling the signal vias 108 to the third conductive layer 120 and underling the signal pads 106. For instance, the ground layer 214 may be co-planar with the surface signal pads 206, or may be between the surface signal pads 206 and the interior layer of the PCB having the connecting traces 210. Such a configuration may alternatively or additionally be used to provide improved signal integrity at high frequencies.

An advantage of a design according to the examples illustrated herein may be increasing the lowest frequency of undesired waveguide modes in the footprint by as a factor as high as 2. The undesired excitations may be pushed outside of the desired operating frequency range of the footprint (e.g., up to 70 GHz, such as operating over a range that includes 60-70 GHz). For instance, the lowest frequency waveguide mode supported in the antipads may be increased by a factor as high as 2. Alternatively or additionally, by having ground layers 214 and 218 both above and below the conductive traces 210, respectively, both the TE₁₀ and TE₀₁ waveguide modes in the conductive traces 210 may be controlled.

In some embodiments, the substrate may have a second surface opposite the surface 202, and the signal vias 208 may be offset from the second surface. For example, the signal vias 208 may be aligned with openings into the surface 202. In some embodiments, while being offset from the second surface, the signal vias 208 may extend at least between a layer having the connecting traces 210 and the signal contact pads 206 disposed on the surface 202. For example, as shown in FIG. 3C, the signal vias 208 may extend from signal contact pads 206 on surface 202 to connecting traces 210 on transition layer 205 and terminate at transition layer 205. For instance, the signal vias 208 may be drilled from surface 202 into the substrate and terminate at transition layer 205. In some embodiments, the signal vias 208 may extend less than 20 mils into the substrate, such as less than 10 mils, such as 8 mils. In some embodiments, the signal vias 208 may be formed by drilling into the substrate from the surface 202.

In some embodiments, the signal vias 216 may extend at least between a layer having the connecting traces 210 and the routing layer 220 of the substrate. For example, as shown in FIG. 3C, the signal vias 216 extend from the transition layer 205 to the routing layer 220. In some embodiments, the signal vias 216 may be longer than the signal vias 208. For example, the distance from surface 202 to transition layer 205 may be shorter than the distance from transition layer 205 to routing layer 220.

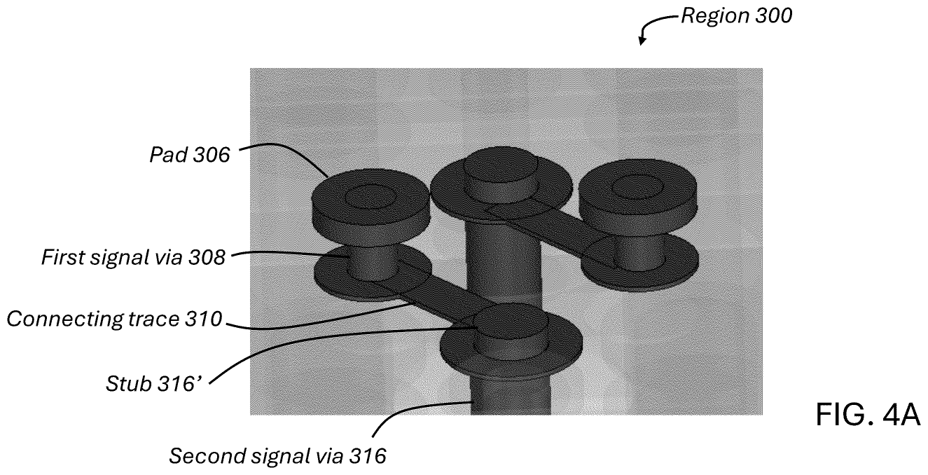

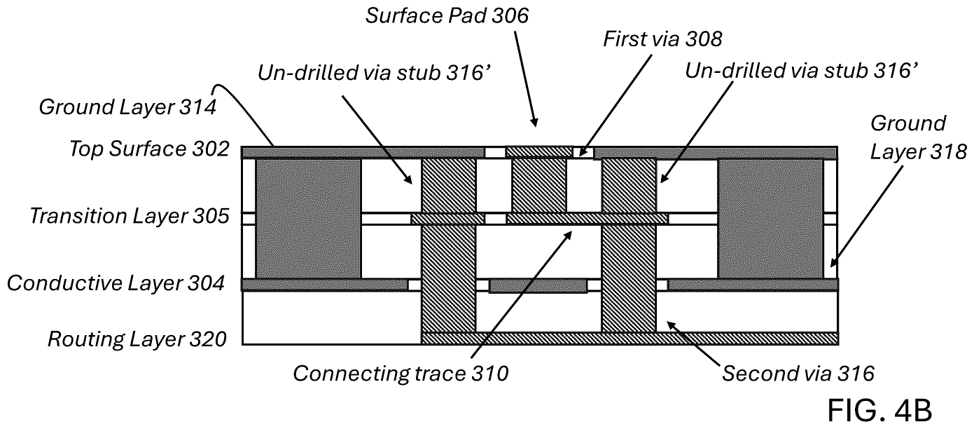

In some embodiments, the ground layer 214 may further include a pair of holes aligned with the signal vias 216. For example, the signal vias 216 may be drilled from the second surface of the substrate (e.g., opposite the surface 202) through to the surface 202. In some embodiments, the holes may cause the signal vias 216 to be offset from surface 202. For example, as shown in FIG. 3A, the holes overlying signal vias 216 do not contain conductive material. In the illustrated embodiment, the signal vias 216 may be further drilled from the surface 202 to remove conductive material from the signal vias 216 when filled from the second surface. In some embodiments, having the signal vias 216 offset from the surface 202 may reduce or eliminate stubs that affect the impedance of signals propagating in the signal vias 216. Other embodiments may have less of an offset between the signal vias 216 and the surface 202 than shown in FIGS. 3A-3D, such as no offset in the example of FIGS. 4A-4B described below.

FIGS. 4A-4B illustrates a portion of an alternative footprint. FIG. 4A illustrates a top view of the footprint with the upper ground layer hidden from view. FIG. 4B illustrates a side view of a cross-section of the footprint of FIG. 4A.

As shown in FIGS. 4A-4B, the footprint includes a region 300, which may be configured as described for region 200. For example, as shown in FIG. 4A, the region 300 includes signal contact pads 306, connecting traces 310, signal vias 308 electrically coupling the signal contact pads 306 and connecting traces 310, and signal vias 316 electrically coupling the connecting traces 310 to a routing layer 320 (FIG. 4B). As shown in FIG. 4B, the signal contact pads 306 and a ground layer 314 are on a top surface 302, the connecting traces 310 are on a transition layer 305, a ground layer 318 is on a conductive layer 304, and traces (e.g., 122) electrically coupled to the signal contact pads 306 are on a routing layer 320.

Region 300 differs from region 200 (FIG. 4A) in that signal vias 316 are not offset from surface 302. As shown in FIG. 4A, the signal vias 316 include stubs 316′ extending from the signal vias 316 towards the surface 302. The configuration of FIGS. 4A-4B may represent an alternative, finished design. Alternatively, the configuration of FIGS. 4A-4B may represent a stage of manufacturing of the portion of the footprint shown in FIGS. 3A and 3B, which might be manufactured by removing the stubs 316′ from the configuration of FIGS. 4A-4B.

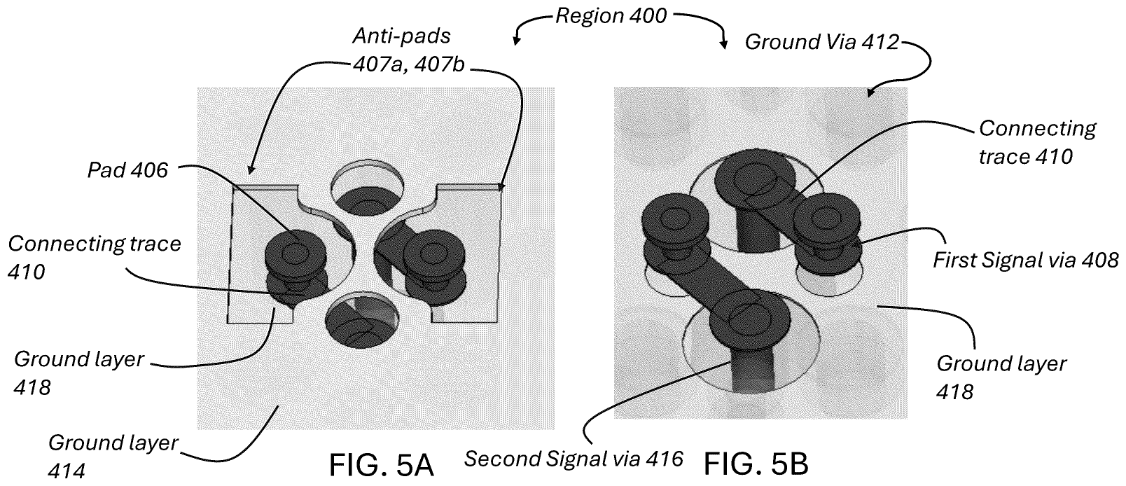

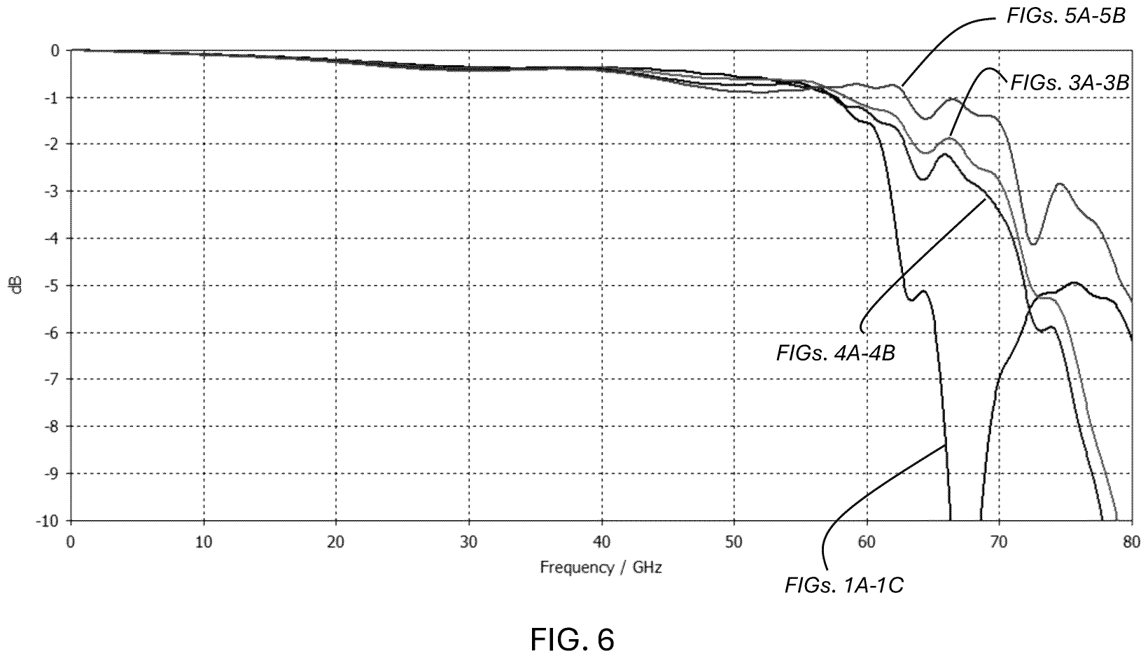

FIGS. 5A-5B illustrate a further alternative connector footprint. FIG. 5A illustrates a top view of the footprint. FIG. 4B illustrates a top view of the footprint with the upper ground layer hidden from view.

As shown in FIGS. 5A-5B, the footprint includes a region 400, which may be configured as described herein for region 200. For example, as shown in FIGS. 5A-5B, the region 400 includes signal contact pads 406, connecting traces 410, signal vias 408 electrically coupling the signal contact pads 406 and connecting traces 410, and signal vias 416 electrically coupling the connecting traces 410 to a routing layer (e.g., 220, not shown). As further shown in FIGS. 5A-5B, a ground layer 414 may be on the surface with signal contact pads 406 and a ground layer 418 may be between the layer having connecting traces 410 and the routing layer.

In some embodiments, variations in structural features that may improve high frequency performance through the connector footprint. For example, as shown in FIGS. 5A-5B, the connecting traces 410 may be wider than the connecting traces 310.

FIG. 6 is a plot showing simulated insertion loss for a signal path through a connector footprint. The four curves show simulated transmission loss for the baseline footprint of FIGS. 1A-1C and the three example footprints shown in FIGS. 3A-3B, 4A-4B and 5A-5B. The simulated data show improved insertion loss between 60 GHz and 70 GHz as compared to the baseline footprint, meaning that the footprint enables operation at a higher frequency and/or over a wider bandwidth.

The simulations are based on a PCB with 6+ layers of PCB and a portion of the signal path in a connector as shown in U.S. Pat. No. 11,637,403 until above the contact tails (e.g., spring contact tails).

One or more of the features described herein may be used in a connector footprint to obtain clear performance gains without significantly increasing the complexity of producing the substrate (e.g., using available and straightforward PCB manufacturing techniques). In some examples, a footprint as described herein may facilitate advantageous routing layer layouts (e.g., using up to 6-6-6 routing) while mounting connectors having broadside-coupled contact tails. Alternatively or additionally, one or more of the techniques described herein may provide improved crosstalk performance.

Additional embodiments of technology described herein are described further below.

In a first example, a substrate, comprises an insulative body comprising a surface, a pair of signal vias, a pair of signal contact pads disposed on the surface, wherein contact pads of the pair are spaced from one another along a first line, and conductive traces interior to the substrate and electrically coupling respective signal contact pads of the pair of signal contact pads and signal vias of the pair of signal vias, wherein signal vias of the pair of signal vias are spaced from one another along a second line disposed at an angle with respect to the first line.

Optionally, the angle is between 45 degrees and 135 degrees.

Optionally, the angle is 90 degrees.

Optionally, the substrate further comprises a second pair of signal vias electrically coupling respective signal contact pads of the pair of signal contact pads and conductive traces of the conductive traces.

Optionally, the insulative body has a second surface opposite the surface, and the substrate further comprises openings into the surface of the insulative body, wherein the openings are aligned with respective signal vias of the second pair of signal vias such that the signal vias of the second pair are offset from the second surface.

Optionally, the signal vias of the second pair of signal vias extend at least between a layer comprising the conductive traces and the signal contact pads disposed on the surface.

Optionally, wherein the second pair of signal vias extend less than 20 mils into the insulative body from the surface.

Optionally, the second pair of signal vias extend less than 10 mils into the insulative body from the surface.

Optionally, the conductive traces electrically couple respective signal vias of the second pair of signal vias and signal vias of the pair of signal vias.

Optionally, the signal vias of the pair of signal vias extend at least between a layer comprising the conductive traces and a routing layer of the substrate.

Optionally, the routing layer comprises a pair of traces coupled to the pair of signal vias, the pair of traces extending parallel to the second line.

Optionally, the substrate further comprises a ground layer offset from the conductive traces interior to the substrate in a direction towards the surface of the insulative body.

Optionally, the ground layer comprises a portion between the signal contact pads of the pair of signal contact pads, and the portion is bisected by the second line.

Optionally, the ground layer has a pair of openings in which the pair of signal contact pads are respectively disposed, with at least a portion of the ground layer between the pair of openings between the pair of signal contact pads.

Optionally, the ground layer is on the surface of the insulative body.

Optionally, the substrate further comprises openings into the surface of the insulative body, wherein the openings are aligned with the pair of signal vias such that the signal vias are offset from the surface.

In a second example, a substrate comprises a connector footprint. The connector footprint comprises a plurality of regions disposed in rows and columns. Each region comprises a pair of conductive pads on a surface of the substrate, a first pair of signal vias, wherein signal vias of the first pair are separated from one another along a first direction, a second pair of signal vias, wherein signal vias of the second pair are separated from one another along a second direction that is orthogonal to the first direction, and wherein the first pair of signal vias interconnect respective ones of the pair of conductive pads and the second pair of signal vias, and each region further comprises conductive traces interconnecting respective ones of the second pair of signal vias and the first pair of signal vias.

Optionally, the pair of conductive pads are separated from one another along the first direction.

Optionally, the pair of conductive pads are aligned with the first pair of signal vias.

Optionally, the connector footprint further comprises a ground layer, and each region further comprises a first portion of the ground layer at least partially surrounding the pair of conductive pads and a second portion of the ground layer between the pair of conductive pads along the first direction.

Optionally, the first portion of the ground layer forms an aperture around the pair of conductive pads and the second portion of the ground layer interconnects the ground layer across the aperture from a first side of the aperture to a second side of the aperture opposite the first side along the second direction.

Optionally, the ground layer further comprises a pair of holes aligned with the second pair of vias.

Optionally, the substrate further comprises a second surface opposite the surface and openings into the surface, wherein the openings are aligned with the first pair of vias, respectively, such that the vias of the first pair of vias are offset from the second surface.

Optionally, the vias of the first pair of vias extend at least between a layer of the substrate that comprises the pair of conductive pads and a layer of the substrate that comprises the conductive traces.

Optionally, the first pair of vias extend less than 20 mils into the substrate from the surface.

Optionally, the first pair of vias extend less than 10 mils into the substrate from the surface. Optionally, the second pair of vias are longer than the first pair of vias.

Optionally, the substrate further comprises a routing layer comprising a pair of traces coupled to the conductive traces via the second pair of vias, the pair of traces extending parallel to the second direction.

In a third example, a substrate comprises an insulative body comprising a surface, a pair of signal vias, a pair of signal contact pads disposed on the surface, conductive traces interior to the substrate and electrically coupling respective signal contact pads of the pair of signal contact pads and signal vias of the pair of signal vias, and a ground layer above the conductive traces interior to the substrate, the ground layer comprising a pair of antipads, each antipad of the pair aligned with a signal contact pad of the pair of signal contact pads.

Optionally, the ground layer comprises a portion between the antipads of the pair of antipads and between the signal contact pads of the pair of signal contact pads.

Optionally, the substrate comprises a plurality of regions. A first region of the plurality of regions comprises the pair of signal vias, the pair of signal contact pads disposed on the surface, and the conductive traces interior to the substrate and electrically coupling respective signal contact pads of the pair of signal contact pads and signal vias of the pair of signal vias. Each of the other regions of the plurality of regions comprises a like pair of signal vias, a like pair of signal contact pads disposed on the surface, and like conductive traces interior to the substrate and electrically coupling respective signal contact pads of the like pair of signal contact pads and like pair signal vias of the pair of signal vias.

Optionally, the plurality of regions are disposed in a rectangular array.

Optionally, the conductive traces of the first region and the like conductive traces of the other regions of the plurality of regions are disposed at the same interior layer.

Optionally, the plurality of regions comprise a connector footprint and the ground layer extends throughout the connector footprint.

Optionally, the substrate further comprises a routing layer comprising a pair of traces coupled to the pair of signal contact pads via the pair of signal vias, wherein the pair of signal contact pads are separated in a first direction and the pair of traces extend in a second direction that is orthogonal to the first direction.

Optionally, the substrate further comprises openings into the surface of the insulative body, wherein the openings are aligned with the pair of signal vias such that the signal vias of the pair of signal vias are offset from the surface.

Optionally, the substrate further comprises a second pair of signal vias extending from the surface into the substrate and electrically coupling the pair of signal contact pads and the conductive traces interior to the substrate, respectively.

Optionally, the substrate further comprises a second surface opposite the surface and openings into the surface aligned with respective signal vias of the second pair of signal vias such that the signal vias of the second pair of signal vias are offset from the second surface.

Optionally, the second pair of signal vias extend less than 20 mils into the substrate from the surface.

Optionally, the second pair of signal vias extend less than 10 mils into the substrate from the surface.

In a fourth example, a substrate comprises insulative material comprising a surface, a pair of signal vias, a pair of signal contact pads disposed on the surface, wherein contact pads of the pair are spaced from one another along a first line, and conductive traces electrically coupling respective signal contact pads of the pair of signal contact pads and signal vias of the pair of signal vias. At least some of the insulative material is disposed between the pair of signal contact pads and the conductive traces, and signal vias of the pair of signal vias are spaced from one another along a second line disposed at an angle with respect to the first line.

Optionally, the substrate further comprises openings into the surface that are aligned with the pair of signal vias such that the signal vias are offset from the surface.

Optionally, the substrate further comprises a routing layer, and the insulative material comprises a first portion disposed between the pair of signal contact pads and the conductive traces and a second portion disposed between the conductive traces and the routing layer.

Optionally, the routing layer comprises a pair of traces electrically coupled to the pair of signal contact pads, respectively, and the pair of traces extend parallel to the second line.

Optionally, the angle is between 45 degrees and 145 degrees. Optionally, the angle is 90 degrees.

Optionally, the substrate further comprises a second pair of signal vias electrically coupling respective signal contact pads of the pair of signal contact pads and conductive traces of the conductive traces, wherein the second pair of signal vias extend through the at least some of the insulative material disposed between the pair of signal contact pads and the conductive traces.

Optionally, the substrate further comprises a second surface opposite the surface and openings into the surface aligned with respective signal vias of the second pair of signal vias such that the signal vias of the second pair of signal vias are offset from the second surface.

Optionally, the second pair of signal vias extend from the surface into the substrate.

Optionally, the second pair of signal vias extend less than 20 mils from the surface into the substrate.

Optionally, the second pair of signal vias extend less than 10 mils from the surface into the substrate.

Optionally, the conductive traces electrically couple respective signal vias of the second pair of signal vias and signal vias of the pair of signal vias.

Optionally, the surface further comprises a ground layer having at least a portion between the pair of signal contact pads along the first line, and the at least some of the insulative material is further disposed between at least the portion of the ground layer and the conductive traces.

Optionally, the surface further comprises a ground layer having a pair of openings in which the pair of signal contact pads are respectively disposed, with at least a portion of the ground layer between the pair of openings between the pair of contact pads, and the at least some of the insulative material further disposed between at least the portion of the ground layer and the conductive traces.

In a fifth example, a substrate comprises a connector footprint. The connector footprint comprises a plurality of regions disposed in rows and columns. Each region comprises a pair of signal contact pads separated from one another along a first direction and conductive material configured as a ground plane. The conductive material comprises a first portion on a first side of the pair of signal contact pads, a second portion on a second side of the pair of signal contact pads that is opposite the first side along a second direction transverse to the first direction, and a third portion disposed between the pair of signal contact pads that connects the first portion to the second portion.

Optionally, the first direction is one of a row direction, along which the rows of the plurality of regions extend, and a column direction, along which the columns of the plurality of regions extend, and the second direction is the other of the row direction and the column direction.

Optionally, the substrate comprises an insulative body comprising a surface and the pairs of signal contact pads and the ground plane conductive material of the plurality of regions are disposed on the surface.

Optionally, the substrate further comprises a first pair of signal vias electrically coupled to the pair of signal contact pads.

Optionally, the substrate further comprises conductive traces interior to the substrate and electrically coupled to the pair of signal contact pads, respectively, via respective signal vias of the first pair of signal vias.

Optionally, the substrate further comprises a second surface opposite the surface and openings into the surface aligned with respective signal vias of the first pair of signal vias such that the signal vias of the first pair of signal vias are offset from the second surface.

Optionally, the substrate further comprises a second pair of signal vias electrically coupled to the pair of signal contact pads, respectively, via respective conductive traces of the conductive traces.

Optionally, the substrate further comprises a routing layer comprising a pair of traces electrically coupled to respective signal contact pads of the pair of signal contact pads, wherein the pair of signal contact pads are separated along a first direction and the pair of traces extend in a second direction orthogonal to the first direction.

Optionally, the ground plane conductive material surrounds the pair of signal contact pads on at least three sides including the first side, the second side, and a third side connecting the first side and the second side.

Optionally, the at least three sides include the first side, the second side, the third side, and a fourth side that is opposite the third side along the first direction.

Optionally, the first and second portions of the ground plane conductive material are connected by the third side to form a first aperture around each of the pair of signal contact pads having a first diameter in the first direction, and the first and second portions of the ground plane conductive material are connected by the third portion to form a second aperture around one of the pair of signal contact pads having a second diameter in the first direction that is at least 50% shorter than the first diameter.

Having thus described several aspects of at least one embodiment of this invention, it is to be appreciated that various alterations, modifications, and improvements will readily occur to those skilled in the art.

Such alterations, modifications, and improvements are intended to be part of this disclosure, and are intended to be within the spirit and scope of the invention. Further, though advantages of the present invention are indicated, it should be appreciated that not every embodiment of the invention will include every described advantage. Some embodiments may not implement any features described as advantageous herein and in some instances. Accordingly, the foregoing description and drawings are by way of example only.

Various aspects of the present invention may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Also, the invention may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

1. A substrate, comprising:
an insulative body comprising a surface;
a pair of signal vias;
a pair of signal contact pads disposed on the surface, wherein contact pads of the pair are spaced from one another along a first line; and
conductive traces interior to the substrate and electrically coupling respective signal contact pads of the pair of signal contact pads and signal vias of the pair of signal vias,
wherein signal vias of the pair of signal vias are spaced from one another along a second line disposed at an angle with respect to the first line.

2. The substrate of claim 1, wherein the angle is between 45 degrees and 135 degrees.

3. The substrate of claim 2, wherein the angle is 90 degrees.

4. The substrate of claim 1, further comprising:
a second pair of signal vias electrically coupling respective signal contact pads of the pair of signal contact pads and conductive traces of the conductive traces.

5-9. (canceled)

10. The substrate of claim 1, wherein:
the signal vias of the pair of signal vias extend at least between a layer comprising the conductive traces and a routing layer of the substrate; and
the routing layer comprises a pair of traces coupled to the pair of signal vias, the pair of traces extending parallel to the second line.

11. (canceled)

12. The substrate of claim 1, further comprising a ground layer offset from the conductive traces interior to the substrate in a direction towards the surface of the insulative body.

13. The substrate of claim 12, wherein:
the ground layer comprises a portion between the signal contact pads of the pair of signal contact pads; and
the portion is bisected by the second line.

14. The substrate of claim 13, wherein the ground layer has a pair of openings in which the pair of signal contact pads are respectively disposed, with at least a portion of the ground layer between the pair of openings between the pair of signal contact pads.

15. The substrate of claim 14, wherein the ground layer is on the surface of the insulative body.

16. (canceled)

17. A substrate comprising a connector footprint, wherein the connector footprint comprises a plurality of regions disposed in rows and columns, each region comprising:
a pair of conductive pads on a surface of the substrate;
a first pair of signal vias, wherein signal vias of the first pair are separated from one another along a first direction;
a second pair of signal vias,
wherein signal vias of the second pair are separated from one another along a second direction that is orthogonal to the first direction, and
wherein the first pair of signal vias interconnect respective ones of the pair of conductive pads and the second pair of signal vias; and
conductive traces interconnecting respective ones of the second pair of signal vias and the first pair of signal vias.

18. The substrate of claim 17, wherein the pair of conductive pads are separated from one another along the first direction.

19. The substrate of claim 17, wherein the pair of conductive pads are aligned with the first pair of signal vias.

20-22. (canceled)

23. The substrate of claim 17, wherein the substrate further comprises:
a second surface opposite the surface; and
openings into the surface, wherein the openings are aligned with the first pair of vias, respectively, such that the vias of the first pair of vias are offset from the second surface.

24. The substrate of claim 17, wherein the vias of the first pair of vias extend at least between a layer of the substrate that comprises the pair of conductive pads and a layer of the substrate that comprises the conductive traces.

25. The substrate of claim 23, wherein the first pair of vias extend less than 20 mils into the substrate from the surface.

26. (canceled)

27. The substrate of claim 17, wherein the second pair of vias are longer than the first pair of vias.

28. The substrate of claim 17, further comprising a routing layer comprising a pair of traces coupled to the conductive traces via the second pair of vias, the pair of traces extending parallel to the second direction.

29-40. (canceled)

41. A substrate, comprising:
insulative material comprising a surface;
a pair of signal vias;
a pair of signal contact pads disposed on the surface, wherein contact pads of the pair are spaced from one another along a first line; and
conductive traces electrically coupling respective signal contact pads of the pair of signal contact pads and signal vias of the pair of signal vias,
wherein at least some of the insulative material is disposed between the pair of signal contact pads and the conductive traces,
wherein signal vias of the pair of signal vias are spaced from one another along a second line disposed at an angle with respect to the first line.

42. The substrate of claim 41, further comprising openings into the surface that are aligned with the pair of signal vias such that the signal vias are offset from the surface.

43. The substrate of claim 41, wherein the substrate further comprises a routing layer, and the insulative material comprises a first portion disposed between the pair of signal contact pads and the conductive traces and a second portion disposed between the conductive traces and the routing layer.

44. The substrate of claim 43, wherein the routing layer comprises a pair of traces electrically coupled to the pair of signal contact pads, respectively, and the pair of traces extend parallel to the second line.

45. The substrate of claim 41, wherein the angle is between 45 degrees and 145 degrees.

46. The substrate of claim 45, wherein the angle is 90 degrees.

47. The substrate of claim 41, further comprising a second pair of signal vias electrically coupling respective signal contact pads of the pair of signal contact pads and conductive traces of the conductive traces, wherein the second pair of signal vias extend through the at least some of the insulative material disposed between the pair of signal contact pads and the conductive traces.

48-51. (canceled)

52. The substrate of claim 47, wherein the conductive traces electrically couple respective signal vias of the second pair of signal vias and signal vias of the pair of signal vias.

53. (canceled)

54. The substrate of claim 41, wherein the surface further comprises a ground layer having a pair of openings in which the pair of signal contact pads are respectively disposed, with at least a portion of the ground layer between the pair of openings, and the at least some of the insulative material further disposed between at least the portion of the ground layer and the conductive traces.

55-65. (canceled)
